(19) United States
(12) Patent Application Publication
(10) Pub. No.: US 2026/0170221 A1
(43) Pub. Date: Jun. 18, 2026

(54) CHARGING DAMAGE PROTECTION FOR BACKSIDE POWER DELIVERY

(71) Applicant: International Business Machines Corporation, Armonk, NY (US)

(72) Inventors: Terence B. Hook, Jericho Center, VT (US); Albert Manhee Chu, Nashua, NH (US)

(21) Appl. No.: 18/981,861

(22) Filed: Dec. 16, 2024

(51) Int. Cl. G06F 30/3953

(52) U.S. Cl. CPC G06F 30/3953

(57) ABSTRACT

A method includes obtaining a plurality of macro cells, wherein each macro cell comprises a corresponding plurality of transistors and determining whether each of the plurality of macro cells is compliant with a set of one or more design rules associated with one or more backside wiring layers. The method includes providing, based on a result of the determining, one or more conductive shunt paths for at least one of the macro cells, where each transistor in each macro cell comprises a respective conductive shunt path between a gate structure and a source/drain region of the corresponding transistor.

### BACKGROUND

The present application relates to semiconductors, and more specifically, to techniques for forming semiconductor structures. Semiconductors and integrated circuit chips have become ubiquitous across various products as they continue to evolve with advancements in cost reduction and miniaturization. One such advancement is the development of backside power delivery networks (BSPDNs), which provide an advanced approach to power delivery within integrated circuits by routing power directly through the backside of the silicon die. BSPDNs provide power directly through the back of the silicon die, which allows for more effective routing and reduced resistance losses, for example.

### SUMMARY

Embodiments described herein provide techniques for protecting against charging damage in backside power delivery architectures.

In one embodiment, a method includes obtaining a plurality of macro cells, where each macro cell comprises a corresponding plurality of transistors and determining whether each of the plurality of macro cells is compliant with a set of one or more design rules associated with one or more backside wiring layers. The method includes providing, based on a result of the determining, one or more conductive shunt paths for at least one of the macro cells, where each transistor in each macro cell comprises a respective conductive shunt path between a gate structure and a source/drain region of the corresponding transistor.

In another embodiment, a computer program product includes a set of one or more computer readable storage media and program instructions, collectively stored in the set of one or more storage media, for causing a processor set to perform the following computer operations: obtain a plurality of macro cells, where each macro cell comprises a corresponding plurality of transistors; determine whether each of the plurality of macro cells is compliant with a set of one or more design rules associated with one or more backside wiring layers; and provide, based on a result of the determining, one or more conductive shunt paths for at least one of the macro cells, where each transistor in each macro cell comprises a respective conductive shunt path between a gate structure and a source/drain region of the corresponding transistor.

In another embodiment, a semiconductor structure includes at least one macro cell comprising one or more backside wiring layers, where the at least one macro cell includes a plurality of transistors. The semiconductor structure further includes a conductive shunt path between a gate structure and a source/drain region of each transistor of the at least one macro.

These and other features and advantages of embodiments described herein will become more apparent from the accompanying drawings and the following detailed description.

### BRIEF DESCRIPTION OF THE DRAWINGS

FIG. 1 depicts a cross-sectional view of a semiconductor structure including a backside power delivery network, according to an illustrative embodiment.

FIG. 2 depicts a schematic diagram of a macro for a backside power delivery network with charging protection elements, according to an illustrative embodiment.

FIG. 3 depicts a schematic diagram of an assembled circuit device including two or more macros, according to an illustrative embodiment.

FIG. 4 is a flow diagram illustrating a method, according to an illustrative embodiment.

FIG. 5 depicts a semiconductor computer-aided design tool, according to an illustrative embodiment.

FIG. 6 is a diagram illustrating a computing environment in which at least one embodiment of the invention can be implemented.

### DETAILED DESCRIPTION

Illustrative embodiments may be described herein in the context of illustrative methods for protecting against charging damage in backside power delivery architectures, along with illustrative apparatus, systems and devices formed using such methods. However, it is to be understood that embodiments are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques are used to reduce the size of FETs while maintaining performance. These include fin-shaped channels in FinFET devices, stacked nanosheet structures for further miniaturization, and more advanced GAA (Gate-All-Around) designs that provide superior control over channel regions compared to traditional planar or even FinFET architectures.

A phenomenon known as the antenna effect can occur during the manufacturing of MOS integrated circuits (ICs). The antenna effect is an effect that can potentially cause yield and reliability problems during the manufacture of metal-oxide-semiconductor (MOS) integrated circuits. Damage is caused by the accumulation of charges collected by floating conductors which act like antennas by focusing energy into a transistor during a plasma process. Specifically, charging may occur during intermediate steps of the manufacturing process when uncovered conductive elements are directly exposed to plasma. When the conductive elements are connected to a gate of a transistor, the plasma-induced charge that has accumulated on the conductive elements can discharge through the gate oxide of the transistor causing damage to the transistor. Plasma induced gate oxide damage can occur during both front and back end of line processes and, thus, is a type of inline charging damage.

In typical bulk chip design flows, macros (also referred to as macro cells or functional subsets) are designed and then assembled into a floorplan. The macros are then wired together using place-and-route tools, for example. It is to be appreciated that the term “macro” as used in this context and elsewhere herein is intended to be broadly construed so as to encompass a self-contained subassembly with a limited number of inputs and outputs, and which can be used in multiple instances in a design or in multiple designs. A given macro can include a substantial number of transistors, typically ranging from thousands or millions. For example, a macro can vary in size from one or more CPU cores to the subunits within a given CPU core, memory caches, input/output (I/O) circuits, etc. More generally, a macro can refer to any circuit unit that is connected to one or more other circuit units with a place-and-route process.

A “place-and-route process” in this context and elsewhere herein generally involves determining the physical placement of various circuit components (e.g., functional subsets and/or macros) on a chip and then routing the interconnections between them. During placement, individual cells or functional blocks are positioned within the design area to achieve high performance and efficient use of space. Once components are placed, routing defines the paths for electrical connections between these components, which may include power and/or signal lines. Advanced place-and-route tools use algorithms to handle the complexity of modern integrated circuits, ensuring that the resulting layout meets design specifications while adhering to manufacturing constraints.

Following the place-and-route steps, antenna design rules are checked. The antenna design rules may include limiting the size of large plates of metal or polysilicon connected to a gate of a transistor and/or restricting a maximum antenna size or antenna ratio for a circuit layout to limit the total charge accumulated on metal connected to a gate to less than a threshold amount, for example.

Any violations of the antenna design rule can be addressed. Common fixes for antenna design rule violations include changing the order of routing layers, adding one or more vias near gates to connect the gate to high-metal layers, and/or adding protection diodes or jumpers. It is noted that the length of the line, and therefore the size of the diode required, is not known until the units are placed and wired.

Conventional techniques for charge protection generally include either bulk charge protection techniques or silicon-on-insulator (SOI) techniques, which are not suitable for BSPDN devices, as the backside wiring is performed separately from the frontside wiring. Illustrative embodiments advantageously provide techniques for protecting against charging damage in BSPDN devices by integrating protection mechanisms at both macro and sub-circuit levels. Such techniques ensure an individual macro is self-contained and protected before being assembled into a larger integrated circuit.

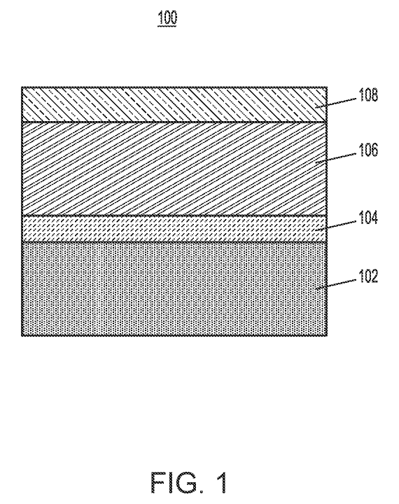

FIG. 1 depicts a cross-sectional view of a semiconductor structure 100, which includes a backside dielectric stack 102, a device layer 104, a frontside dielectric stack 106, and a carrier wafer 108.

In some embodiments, the backside dielectric stack 102 includes various BSPDN structures that provide a power supply path from voltage regulator modules (VRMs) to circuits. These BSPDN structures may include interconnects such as power and ground planes associated with power delivery. Additionally, in some embodiments, the interconnects can alternatively or additionally be used for signal routing, including, but not limited to, power and clock signals.

To provide vertical electrical connections, a plurality of vias may be formed within the backside dielectric layers, allowing connections between different wiring layers and/or to contacts associated with the device layer 104. The wiring layers and vias are typically formed of conductive materials such as tungsten (W), aluminum (Al), cobalt (Co), or ruthenium (Ru).

To ensure reliability and performance, the backside dielectric stack 102 may further include one or more barrier layers and capping layers. The barrier layers, which may be formed of materials such as tantalum (Ta), tantalum nitride (TaN), or titanium nitride (TiN), function to electrically isolate portions of the wiring layers, the vias, and the BSPDN structures from the surrounding dielectric material while also preventing metal diffusion.

Similarly, the backside dielectric stack 102 can include one or more capping layers comprising a suitable capping material (e.g., silicon carbide (SiC) or silicon nitride (SiN)), to provide protection against degradation, enhance stability, and ensure the integrity of the wiring layers, vias, and BSPDN structures.

In some embodiments, the device layer 104 includes a plurality of active semiconductor devices, such as transistors (e.g., MOSFET devices and/or CMOS devices). For instance, a transistor in the device layer 104 may comprise one or more source regions, one or more drain regions, one or more channel regions, and one or more gate stack structures. Each gate structure typically includes a gate dielectric layer and a metal gate portion. The gate dielectric layer may include high-k dielectric materials such as hafnium oxide (HfO₂), zirconium dioxide (ZrO₂), hafnium zirconium oxide, aluminum oxide (Al₂O₃), or tantalum oxide (Ta₂O₅). Other examples of high-k materials include, but are not limited to, metal oxides such as hafnium silicon oxynitride, lanthanum oxide, lanthanum aluminum oxide, and various other suitable materials.

The metal gate portion can include a work-function metal (WFM) layer, which may comprise materials such as titanium nitride (TiN), tantalum nitride (TaN), or ruthenium (Ru) for pFET devices. For nFET devices, the WFM layer can include materials such as TiN, titanium aluminum nitride (TiAlN), titanium aluminum carbon nitride (TiAlCN), tantalum aluminum carbide (TaAlC), or lanthanum-doped TiN or TaN. The metal gate portion may also include a gate metal layer, which can comprise materials such as tungsten, cobalt, zirconium, tantalum, titanium, aluminum, ruthenium, or various combinations of metal carbides, nitrides, or transition metal aluminides, deposited over the WFM layer and the gate dielectric layer. It should be appreciated that various other materials may be used for the metal gate portions as desired.

The device layer 104 may further include one or more contacts and one or more vias that connect the active devices to the wires in the backside dielectric stack 102 and/or the wires in the frontside dielectric stack 106. The contacts and vias are typically made from conductive materials, such as tungsten (W) or cobalt (Co), and are often embedded within insulating dielectric layers to maintain electrical isolation.

Additionally, the device layer 104 may include isolation structures, such as shallow trench isolation (STI) regions, and a semiconductor substrate layer formed from silicon (Si) or other suitable materials, such as silicon carbide or gallium nitride. The isolation structures are designed to electrically separate individual transistors and mitigate parasitic interactions between adjacent devices. Similar to the backside dielectric stack 102, the device layer 104 may incorporate barrier layers to enhance device performance and longevity and/or capping layers to protect against environmental factors and mechanical stress.

In some embodiments, the frontside dielectric stack 106 includes one or more layers of dielectric material comprising materials such as silicon nitride, silicon dioxide, or low-k dielectrics. The frontside dielectric stack 106 further includes one or more frontside wiring layers formed within the dielectric layers for power delivery and/or signal routing. In some embodiments, the frontside wiring layers can comprise one or more suitable conductive materials. A plurality of vias may be formed within the frontside dielectric layers, allowing connections between different wiring layers and/or to the contacts associated with the device layer 104. Similar to the backside dielectric stack 102, the frontside dielectric stack 106 may include a plurality of vias that allow electrical connections and incorporate capping layers, such as silicon carbide (SiC) or silicon nitride (SiN), to protect the frontside wiring layers and vias. The frontside wiring layers and the vias provide electrical connections to various frontside back-end-of-line (BEOL) interconnect structures, for example.

In an illustrative embodiment, a carrier wafer may be formed of materials similar to that of the semiconductor substrate layer and may be formed over the frontside dielectric stack using a wafer bonding process, such as dielectric-to-dielectric bonding.

In some embodiments, the semiconductor structure 100 can represent a macro that is configured to be assembled with one or more other macros or the semiconductor structure 100 can alternatively represent two or more macros that have already been assembled, as described in more detail elsewhere herein.

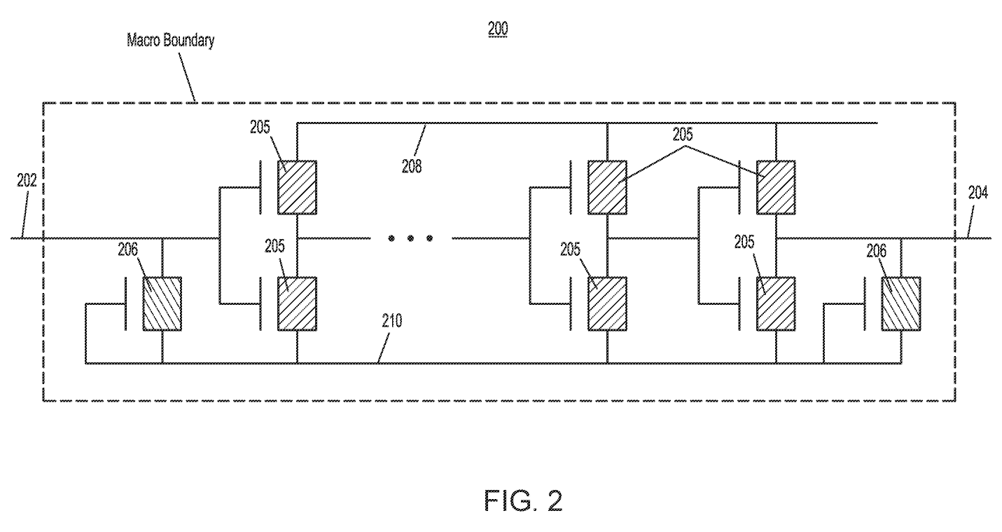

FIG. 2 depicts a schematic diagram of a macro 200 with charging protection elements, according to an illustrative embodiment. The macro 200 includes an input signal 202, an output signal 204, a plurality of transistors 205, at least two protection devices 206, a power/voltage supply (Vdd) bus 208, and a ground (GND) bus 210.

In some embodiments, the protection devices 206 correspond to shunt devices (e.g., shunt FETs) that provide conductive shunt paths between gate structures and source/drain regions of at least one some of the transistors 205. In some embodiments, connections crossing the macro boundary (e.g., the input signal 202 and/or the output signal 204) can also be configured with corresponding respective ones of the protection devices 206, as shown in FIG. 2. The protection devices 206 ensure that any signals crossing the macro boundary are properly managed to prevent differential charging damage, thereby ensuring robust immunity against charging events when the macro is assembled into a functional chip (e.g., an integrated circuit). In some embodiments, the conductive paths for at least some of the transistors 205 is provided by the previous stage that drives them, and thus separate protection devices are not necessarily needed for such devices. If any of the transistors 205 are not protected by the previous stage, then additional protection devices 206 can be added.

For instance, a given protection device 206 can comprise a normally-off FET device. A normally-off FET device can comprise a diode-connected transistor that has its gate tied to its source, which can provide an alternate path for current under certain conditions (e.g., overvoltage or excess current). Accordingly, the protection devices 206 ensure that any signals crossing macro boundaries are properly managed to prevent differential charging damage, thereby ensuring robust immunity against charging events during chip assembly.

In some embodiments, each of the conductive shunt paths are designed to be within a specified distance from the maximum extent of backside wiring layers connected to a corresponding one of the transistors 205. Each of the protection devices 206 can alternatively or additionally be sized proportionally to an area of conductors attached to a corresponding one of the transistors 205.

According to some embodiments, the macro 200 is designed and individually tested for compliance with frontside antenna design rules prior to it being assembled with another macro.

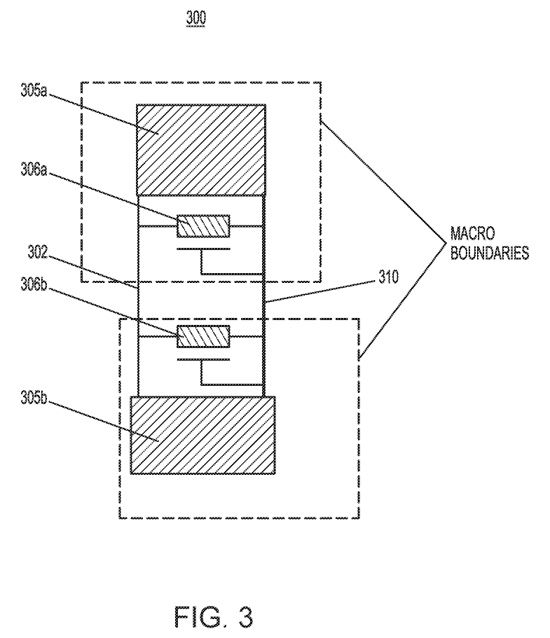

FIG. 3 depicts a schematic diagram of an assembled circuit device 300, according to an illustrative embodiment. The assembled circuit device 300 includes a first macro comprising one or more transistors 305a and at least one protection device 306a, and a second macro comprising one or more transistors 305b and at least one protection device 306b. The first macro and the second macro include at least one frontside connection 302 corresponding to an input signal, and at least one backside connection 310 to provide backside power delivery, for example. As can be seen from FIG. 3, the protection device 306a and the protection device 306b are positioned to protect the respective transistors 305a and 305b when being assembled together, for example, using a place-and-route process.

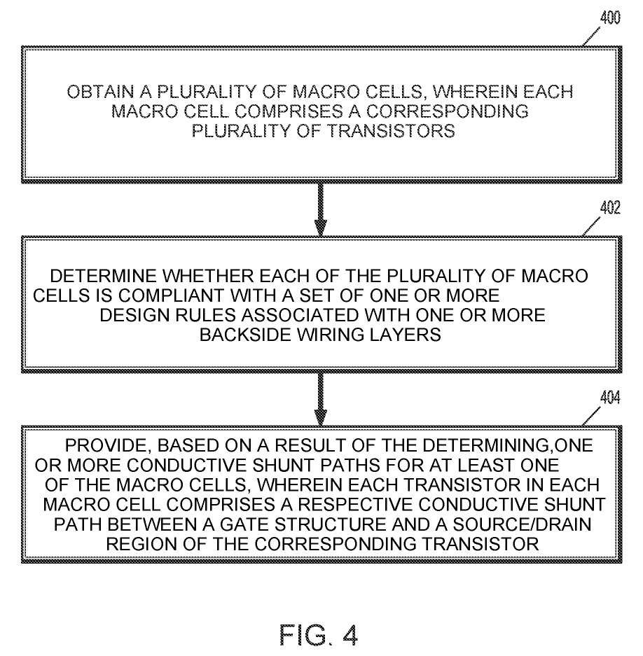

FIG. 4 illustrates a flow diagram of a method for fabricating a semiconductor device which is configured with charging protection elements, according to an illustrative embodiment. For example, in some embodiments, FIG. 4 illustrates a fabrication process flow which implements various process modules to fabricate an exemplary semiconductor device structure such as shown in FIG. 2 and/or FIG. 3.

Step 400 includes obtaining a plurality of macro cells, wherein each macro cell comprises a corresponding plurality of transistors.

Step 402 includes determining whether each of the plurality of macro cells is compliant with a set of one or more design rules associated with one or more backside wiring layers.

Step 404 includes providing, based on a result of the determining, one or more conductive shunt paths for at least one of the macro cells, wherein each transistor in each macro cell comprises a respective conductive shunt path between a gate structure and a source/drain region of the corresponding transistor.

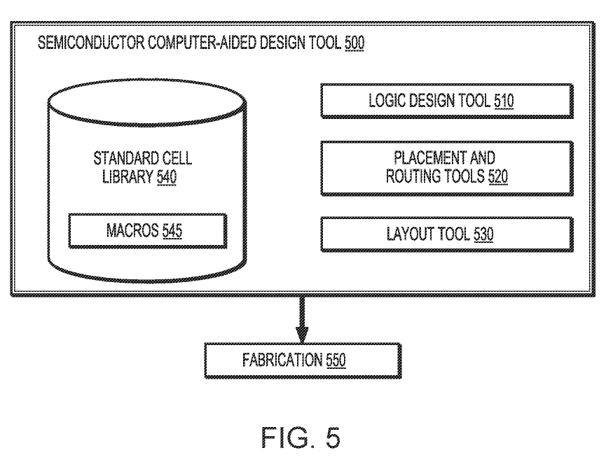

FIG. 5 schematically illustrates a semiconductor computer-aided design (CAD) tool 500 which comprises a logic design tool 510, placement and routing tools 520, a layout tool 530, and a standard cell library 540 comprising macros 545. The standard cell library 540 comprises a plurality of standard cells for one or more semiconductor technologies, wherein each standard cell comprises a group of transistors and interconnect structures which provides a Boolean logic function (e.g., AND, NAND, OR, NOR, XOR, etc.), a storage function (e.g., latches, flip-flops, etc.), or more complex standard cells (e.g., adders, multiplexers, memory, etc.). It is assumed that at least some of the more complex standard cells, or combinations of standard cells, correspond to macros, such as the macros discussed above in conjunction with FIGS. 1-3.

The logic design tool 510 implements logic synthesis methods to generate a gate level representation (e.g., net list) of a given integrated circuit design using various component cells in the standard cell library 540. As is known in the art, a netlist is a nodal description of transistors, of their connections to each other, and of their terminals (ports) to the external environment, which provides a schematic view of the given circuit design. The logic design tool 510 is utilized to generate a net list for a given integrated circuit design based on target logical behaviors and constraints for the given design. In particular, the logic design tool 510 implements logic synthesis techniques and tools which are configured to synthesize a gate-level net list based on a hardware description (e.g., a register transfer level (RTL) file, or any other suitable abstract form of desired circuit behavior), and based on suitable standard component cells selected from the standard cell library 540. The logic design tool 510 utilizes information in a particular library to make appropriate decisions and component selections to build the integrated circuit design.

The logical and netlist views are useful for abstract (algebraic) simulation, and not device fabrication, whereas the placement and routing tools 520 and the layout tool 530 are utilized to design a physical representation of the given integrated circuit comprising standard cells. In particular, the placement and routing tools 520 implement placement methods that are configured to assign the various library components in the net list to non-overlapping locations on an integrated circuit die area, and construct one or more signal distribution networks to make connections to and between the component logic cells in the integrated circuit design. In particular, the placement tool places the various interrelated component cells of a given logic design in two-dimensional spatial relationship that can be fabricated on a chip, and the routing tool assigns predefined routing tracks which provide signal (interconnect) lines for passing signals between the component cells. For example, in this process, a signal distribution network, such as a clock distribution network or a data signal distribution network, is constructed and added in the integrated circuit design. The routing process adds the wiring which is needed to properly connect the placed component cells while obeying all design rules (e.g., antenna design rules) for the integrated circuit design. Techniques for placement and routing are well known to those of ordinary skill in the art.

The layout tool 530 implements methods that are configured to generate a three-dimensional representation of the actual circuit structures (e.g., regions of doped semiconductor, insulated regions, and metal lines) needed to implement the logic design. The layout tool 530 generates a “layout” view which comprises a lowest level of design abstraction. The layout comprises base layers which correspond to the different structures of transistor devices, and wiring layers and via layers which form connections to the terminals of the transistor devices. The layout view generated by the layout tool 530 is used in a fabrication process 550 to fabricate the given integrated circuit.

Semiconductor devices and methods for forming the same in accordance with the above-described techniques can be employed in various applications, hardware, and/or electronic systems. Suitable hardware and systems for implementing embodiments may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments. Given the teachings provided herein, one of ordinary skill in the art will be able to contemplate other implementations and applications of embodiments.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

In one embodiment, a method includes obtaining a plurality of macro cells, where each macro cell comprises a corresponding plurality of transistors and determining whether each of the plurality of macro cells is compliant with a set of one or more design rules associated with one or more backside wiring layers. The method includes providing, based on a result of the determining, one or more conductive shunt paths for at least one of the macro cells, where each transistor in each macro cell comprises a respective conductive shunt path between a gate structure and a source/drain region of the corresponding transistor.

The method of the illustrative embodiment advantageously provides robust protection against charging damage in backside power delivery architectures by ensuring that each macro is self-contained and protected before being assembled into an integrated circuit, thereby reducing the risk of damage during manufacturing and improving overall reliability and performance.

In embodiments, the set of one or more design rules may comprise one or more antenna design rules.

In embodiments, the method may further include assembling the plurality of macro cells into a functional chip using a place-and-route process.

In embodiments, the method may include determining, prior to assembling the plurality of macro cells into the functional chip, that each macro cell is compliant with a set of one or more design rules associated with one or more frontside wiring layers. Such embodiments advantageously provide improved charging damage protection by verifying compliance with design rules associated with both backside and frontside wiring layers before assembling the macros into a functional chip.

In embodiments, the conductive shunt path for each transistor in each macro cell may be less than a specified distance from a maximum extent of the backside wiring layers connected to the transistor. Such embodiments advantageously implement proximity-based design rules, which can further reduce the likelihood of antenna effects causing damage during assembly.

In embodiments, a width of the conductive shunt path corresponding to a given transistor may be proportional to an area of backside conductors attached to the given transistor.

In embodiments, at least one of the transistors corresponding to a given one of the macro cells may include a node connection that crosses a boundary to another one of the plurality of macro cells. Such embodiments advantageously protect against charging damage when assembling different macros by ensuring node connections between macros are protected.

In embodiments, the method may include placing a diode protection element along at least one frontside interconnect, where a size of the diode protection element is based on an antenna associated with the at least one frontside interconnect. Such embodiments advantageously enhance protection against charging damage by placing diode protection to prevent damage caused by excessive currents or voltages on the frontside interconnects.

In embodiments, the source/drain region of a given one of the transistors may be considered conductive independent of a state of the corresponding gate structure.

In embodiments, each of the macro cells may include a limited number of inputs and/or outputs.

In embodiments, each of the macro cells may include between 1,000 and 1,000,000 transistors.

In another embodiment, a computer program product includes a set of one or more computer readable storage media and program instructions, collectively stored in the set of one or more storage media, for causing a processor set to perform the following computer operations: design a plurality of macros that are individually compliant with a set of one or more design rules associated with one or more backside wiring layers, where each macro comprises a corresponding plurality of transistors, provide, for each transistor in each macro, a conductive shunt path between a gate structure and a source/drain region of the corresponding transistor, and assemble the plurality of macros into a functional chip using a place-and-route process.

The computer program product of the illustrative embodiment advantageously provides robust protection against charging damage in backside power delivery architectures by ensuring that each macro is self-contained and protected before being assembled into an integrated circuit, thereby reducing the risk of damage during manufacturing and improving overall reliability and performance.

In embodiments, the program instructions may further cause the processor set to assemble the plurality of macro cells into a functional chip using a place-and-route process.

In embodiments, the program instructions may further cause the processor set to determine, prior to assembling the plurality of macro cells into the functional chip, that each macro cell is compliant with a set of one or more design rules associated with one or more frontside wiring layers.

In embodiments, the conductive shunt path for each transistor in each macro cell may be less than a specified distance from a maximum extent of the backside wiring layers connected to the transistor.

In embodiments, a width of the conductive shunt path corresponding to a given transistor is proportional to an area of backside conductors attached to the given transistor.

In embodiments, at least one of the transistors corresponding to a given one of the macro cells may include a node connection that crosses a boundary to another one of the plurality of macro cells.

In embodiments, the program instructions may further cause the processor set to place a diode protection element along at least one frontside interconnect, where a size of the diode protection element is based on an antenna associated with the at least one frontside interconnect.

In embodiments, the source/drain region of a given one of the transistors may be considered conductive independent of a state of the corresponding gate structure.

In another embodiment, a semiconductor structure includes a plurality of macros that are individually compliant with a set of one or more design rules associated with one or more backside wiring layers, where each macro includes a corresponding plurality of transistors. The semiconductor structure includes a conductive shunt path between a first gate structure and a first source/drain region of each transistor of each macro.

The semiconductor structure of the illustrative embodiment advantageously provides robust protection against charging damage in backside power delivery architectures by ensuring that each macro was self-contained and protected when the macros were assembled, thereby improving overall device reliability and performance.

In embodiments, the at least one macro cell may include a first protection device connected to an input of the at least one macro cell and a second protection device connected to an output of the at least one macro cell, where the first protection device and the second protection device comprise a respective shunt transistor.

The above-described embodiments advantageously provide robust protection against charging damage for BSPDN semiconductor devices. For example, some embodiments ensure that each macro is individually compliant with both frontside and backside antenna design rules prior to assembly into a functional chip. By incorporating conductive shunt paths between gate structures and source/drain regions, such embodiments effectively prevent antenna effects that could otherwise cause damage when assembling two or more macros into a functional chip.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 600 contains an example of an environment for the execution of at least some of the computer code involved in performing the inventive methods, such as semiconductor computer-aided design code in block 700. In addition to block 700, computing environment 600 includes, for example, computer 601, wide area network (WAN) 602, end user device (EUD) 603, remote server 604, public cloud 605, and private cloud 606. In this embodiment, computer 601 includes processor set 610 (including processing circuitry 620 and cache 621), communication fabric 611, volatile memory 612, persistent storage 613 (including operating system 622 and block 700, as identified above), peripheral device set 614 (including user interface (UI) device set 623, storage 624, and Internet of Things (IoT) sensor set 625), and network module 615. Remote server 604 includes remote database 630. Public cloud 605 includes gateway 640, cloud orchestration module 641, host physical machine set 642, virtual machine set 643, and container set 644.

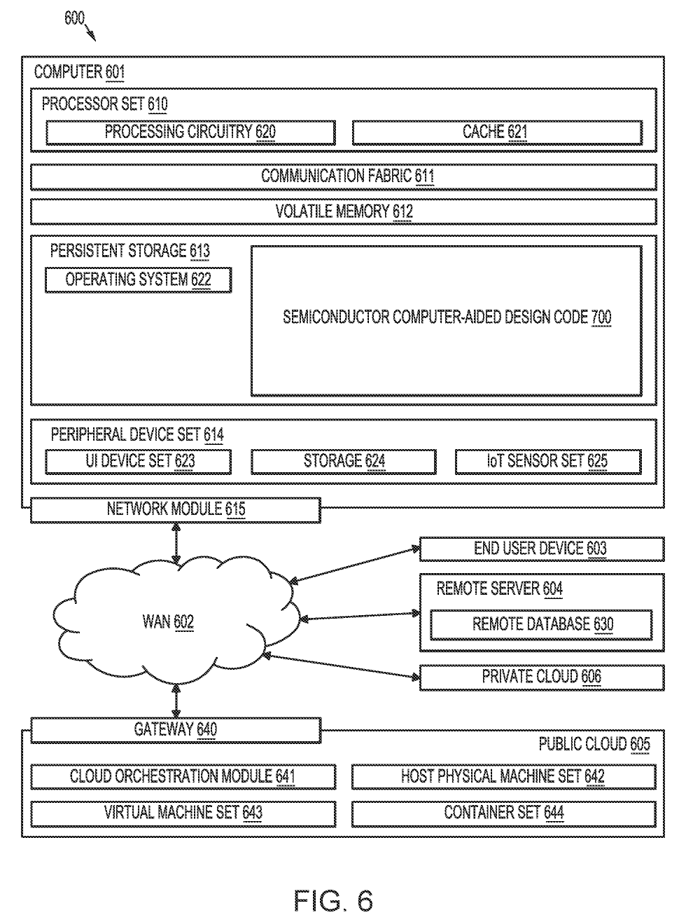

Computer 601 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 630. As is well understood in the art of computer technology, and depending upon the technology, performance of a computer-implemented method may be distributed among multiple computers and/or between multiple locations. On the other hand, in this presentation of computing environment 600, detailed discussion is focused on a single computer, specifically computer 601, to keep the presentation as simple as possible. Computer 601 may be located in a cloud, even though it is not shown in a cloud in FIG. 6. On the other hand, computer 601 is not required to be in a cloud except to any extent as may be affirmatively indicated.

Processor set 610 includes one, or more, computer processors of any type now known or to be developed in the future. Processing circuitry 620 may be distributed over multiple packages, for example, multiple, coordinated integrated circuit chips. Processing circuitry 620 may implement multiple processor threads and/or multiple processor cores. Cache 621 is memory that is located in the processor chip package(s) and is typically used for data or code that should be available for rapid access by the threads or cores running on processor set 610. Cache memories are typically organized into multiple levels depending upon relative proximity to the processing circuitry. Alternatively, some, or all, of the cache for the processor set 610 may be located “off chip.” In some computing environments, processor set 610 may be designed for working with qubits and performing quantum computing.

Computer-readable program instructions are typically loaded onto computer 601 to cause a series of operational steps to be performed by processor set 610 of computer 601 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 621 and the other storage media discussed below. The program instructions, and associated data, are accessed by processor set 610 to control and direct performance of the inventive methods. In computing environment 600, at least some of the instructions for performing the inventive methods may be stored in block 700 in persistent storage 613.

Communication fabric 611 is the signal conduction path that allows the various components of computer 601 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 612 is any type of volatile memory now known or to be developed in the future. Examples include dynamic type random access memory (RAM) or static type RAM. Typically, volatile memory 612 is characterized by random access, but this is not required unless affirmatively indicated. In computer 601, the volatile memory 612 is located in a single package and is internal to computer 601, but, alternatively or additionally, the volatile memory may be distributed over multiple packages and/or located externally with respect to computer 601.

Persistent storage 613 is any form of non-volatile storage for computers that is now known or to be developed in the future. The non-volatility of this storage means that the stored data is maintained regardless of whether power is being supplied to computer 601 and/or directly to persistent storage 613. Persistent storage 613 may be a read only memory (ROM), but typically at least a portion of the persistent storage allows writing of data, deletion of data and re-writing of data. Some familiar forms of persistent storage include magnetic disks and solid state storage devices. Operating system 622 may take several forms, such as various known proprietary operating systems or open source Portable Operating System Interface-type operating systems that employ a kernel. The code included in block 700 typically includes at least some of the computer code involved in performing the inventive methods.

Peripheral device set 614 includes the set of peripheral devices of computer 601. Data communication connections between the peripheral devices and the other components of computer 601 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 623 may include components such as a display screen, speaker, microphone, wearable devices (such as goggles and smart watches), keyboard, mouse, printer, touchpad, game controllers, and haptic devices. Storage 624 is external storage, such as an external hard drive, or insertable storage, such as an SD card. Storage 624 may be persistent and/or volatile. In some embodiments, storage 624 may take the form of a quantum computing storage device for storing data in the form of qubits. In embodiments where computer 601 is required to have a large amount of storage (for example, where computer 601 locally stores and manages a large database) then this storage may be provided by peripheral storage devices designed for storing very large amounts of data, such as a storage area network (SAN) that is shared by multiple, geographically distributed computers. IoT sensor set 625 is made up of sensors that can be used in Internet of Things applications. For example, one sensor may be a thermometer and another sensor may be a motion detector.

Network module 615 is the collection of computer software, hardware, and firmware that allows computer 601 to communicate with other computers through WAN 602. Network module 615 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 615 are performed on the same physical hardware device. In other embodiments (for example, embodiments that utilize software-defined networking (SDN)), the control functions and the forwarding functions of network module 615 are performed on physically separate devices, such that the control functions manage several different network hardware devices. Computer-readable program instructions for performing the inventive methods can typically be downloaded to computer 601 from an external computer or external storage device through a network adapter card or network interface included in network module 615.

WAN 602 is any wide area network (for example, the internet) capable of communicating computer data over non-local distances by any technology for communicating computer data, now known or to be developed in the future. In some embodiments, the WAN 602 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 603 is any computer system that is used and controlled by an end user (for example, a customer of an enterprise that operates computer 601), and may take any of the forms discussed above in connection with computer 601. EUD 603 typically receives helpful and useful data from the operations of computer 601. For example, in a hypothetical case where computer 601 is designed to provide a recommendation to an end user, this recommendation would typically be communicated from network module 615 of computer 601 through WAN 602 to EUD 603. In this way, EUD 603 can display, or otherwise present, the recommendation to an end user. In some embodiments, EUD 603 may be a client device, such as thin client, heavy client, mainframe computer, desktop computer and so on.

Remote server 604 is any computer system that serves at least some data and/or functionality to computer 601. Remote server 604 may be controlled and used by the same entity that operates computer 601. Remote server 604 represents the machine(s) that collect and store helpful and useful data for use by other computers, such as computer 601. For example, in a hypothetical case where computer 601 is designed and programmed to provide a recommendation based on historical data, then this historical data may be provided to computer 601 from remote database 130 of remote server 604.

Public cloud 605 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 605 is performed by the computer hardware and/or software of cloud orchestration module 641. The computing resources provided by public cloud 605 are typically implemented by virtual computing environments that run on various computers making up the computers of host physical machine set 642, which is the universe of physical computers in and/or available to public cloud 605. The virtual computing environments (VCEs) typically take the form of virtual machines from virtual machine set 643 and/or containers from container set 644. It is understood that these VCEs may be stored as images and may be transferred among and between the various physical machine hosts, either as images or after instantiation of the VCE. Cloud orchestration module 641 manages the transfer and storage of images, deploys new instantiations of VCEs and manages active instantiations of VCE deployments. Gateway 640 is the collection of computer software, hardware, and firmware that allows public cloud 605 to communicate through WAN 602.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 606 is similar to public cloud 605, except that the computing resources are only available for use by a single enterprise. While private cloud 606 is depicted as being in communication with WAN 602, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 605 and private cloud 606 are both part of a larger hybrid cloud.

Cloud computing services and/or microservices (not separately shown in FIG. 6): private and public clouds 606 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider’s systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
obtaining a plurality of macro cells, wherein each macro cell comprises a corresponding plurality of transistors;
determining whether each of the plurality of macro cells is compliant with a set of one or more design rules associated with one or more backside wiring layers; and
providing, based on a result of the determining, one or more conductive shunt paths for at least one of the macro cells, wherein each transistor in each macro cell comprises a respective conductive shunt path between a gate structure and a source/drain region of the corresponding transistor.

2. The method of claim 1, further comprising:
assembling the plurality of macro cells into a functional chip using a place-and-route process.

3. The method of claim 2, further comprising:
determining, prior to assembling the plurality of macro cells into the functional chip, that each macro cell is compliant with a set of one or more design rules associated with one or more frontside wiring layers.

4. The method of claim 1, wherein the conductive shunt path for each transistor in each macro cell is less than a specified distance from a maximum extent of the backside wiring layers connected to the transistor.

5. The method of claim 1, wherein a width of the conductive shunt path corresponding to a given transistor is proportional to an area of backside conductors attached to the given transistor.

6. The method of claim 1, wherein at least one of the transistors corresponding to a given one of the macro cells comprises a node connection that crosses a boundary to another one of the plurality of macro cells.

7. The method of claim 1, further comprising:
placing a diode protection element along at least one frontside interconnect, wherein a size of the diode protection element is based on an antenna associated with the at least one frontside interconnect.

8. The method of claim 1, wherein the source/drain region of a given one of the transistors is considered conductive independent of a state of the corresponding gate structure.

9. The method of claim 1, wherein each of the macro cells comprises a limited number of inputs and/or outputs.

10. The method of claim 1, wherein each of the macro cells comprises between 1,000 and 1,000,000 transistors.

11. A computer program product comprising:
a set of one or more computer readable storage media;
program instructions, collectively stored in the set of one or more storage media, for causing a processor set to perform the following computer operations:
obtain a plurality of macro cells, wherein each macro cell comprises a corresponding plurality of transistors;
determine whether each of the plurality of macro cells is compliant with a set of one or more design rules associated with one or more backside wiring layers; and
provide, based on a result of the determining, one or more conductive shunt paths for at least one of the macro cells, wherein each transistor in each macro cell comprises a respective conductive shunt path between a gate structure and a source/drain region of the corresponding transistor.

12. The computer program product of claim 11, wherein the program instructions further cause the processor set to perform the following computer operation:
assemble the plurality of macro cells into a functional chip using a place-and-route process.

13. The computer program product of claim 12, wherein the program instructions further cause the processor set to perform the following computer operation:
determine, prior to assembling the plurality of macro cells into the functional chip, that each macro cell is compliant with a set of one or more design rules associated with one or more frontside wiring layers.

14. The computer program product of claim 11, wherein the conductive shunt path for each transistor in each macro cell is less than a specified distance from a maximum extent of the backside wiring layers connected to the transistor.

15. The computer program product of claim 11, wherein a width of the conductive shunt path corresponding to a given transistor is proportional to an area of backside conductors attached to the given transistor.

16. The computer program product of claim 11, wherein at least one of the transistors corresponding to a given one of the macro cells comprises a node connection that crosses a boundary to another one of the plurality of macro cells.

17. The computer program product of claim 11, wherein the program instructions further cause the processor set to perform the following computer operation:
place a diode protection element along at least one frontside interconnect, wherein a size of the diode protection element is based on an antenna associated with the at least one frontside interconnect.

18. The computer program product of claim 11, wherein the source/drain region of a given one of the transistors is considered conductive independent of a state of the corresponding gate structure.

19. A semiconductor structure comprising:
at least one macro cell comprising one or more backside wiring layers, wherein the at least one macro cell comprises a plurality of transistors; and
a conductive shunt path between a gate structure and a source/drain region of each transistor of the at least one macro.

20. The semiconductor structure of claim 19, wherein the at least one macro cell comprises a first protection device connected to an input of the at least one macro cell and a second protection device connected to an output of the at least one macro cell, wherein the first protection device and the second protection device comprise a respective shunt transistor.
